(19) United States
(12) Patent Application Publication
(10) Pub. No.: US 2015/0372179 A1
(43) Pub. Date: Dec. 24, 2015

(54) MULTI-JUNCTION SOLAR CELL, METHODS FOR THE PRODUCTION THEREOF, AND USES THEREOF

(71) Applicant: FRAUNHOFER-GESELLSCHAFT ZUR FÖRDERUNG DER ANGEWANDTEN FORSCHUNG E. V., München (DE)

(72) Inventors: Frank Dimroth, Gundelfingen (DE); Andreas W. Bett, Freiburg (DE)

(73) Assignee: Fraunhofer-Gesellschaft Zur Forderung Der Angewandten Forschung E.V., Munchen (DE)

(21) Appl. No.: 14/764,749

(22) PCT Filed: Feb. 10, 2014
(86) PCT No.: PCT/EP2014/052552

§ 371 Date: Jul. 30, 2015

(30) Foreign Application Priority Data
Feb. 8, 2013 (DE) 10 2013 002 298.3

(51) Int. Cl. H01L 31/0687; H01L 31/054; H01L 31/0216; H01L 31/041; H01L 31/18; H01L 31/0304

(52) U.S. Cl. CPC H01L 31/0687; H01L 31/1892; H01L 31/03046; H01L 31/0304; H01L 31/1844; H01L 31/184; H01L 31/02168; H01L 31/041; H01L 31/054

(57) ABSTRACT

A multi-junction solar cell having at least three p-n junctions is proposed, which comprises a rear-side subcell comprising GaSb, which has at least one p-n junction, and a front-side subcell which has at least two p-n junctions and which is characterised in that the rear-side subcell has a ≧2%, in particular >4%, larger lattice constant than the front-side subcell and the two subcells are connected to each other via an optically transparent and electrically conductive wafer-bond connection. The multi-junction solar cell achieves a high absorption up to the band gap energy of the lowermost GaSb-comprising subcell and a photoelectric voltage which is increased relative to multi-junction solar cells from the state of the art. Furthermore, methods for the production of the multi-junction solar cell according to the invention are presented and uses of the multi-junction solar cell according to the invention are indicated.

A multi-junction solar cell having at least three p-n junctions is proposed, which comprises a rear-side subcell comprising GaSb, which has at least one p-n junction, and a front-side subcell which has at least two p-n junctions and which is characterised in that the rear-side subcell has a ≧2%, in particular >4%, larger lattice constant than the front-side subcell and the two subcells are connected to each other via an optically transparent and electrically conductive wafer-bond connection. The multi-junction solar cell achieves a high absorption up to the band gap energy of the lowermost GaSb-comprising subcell and a photoelectric voltage which is increased relative to multi-junction solar cells from the state of the art. Furthermore, methods for the production of the multi-junction solar cell according to the invention are presented and uses of the multi-junction solar cell according to the invention are indicated.

It is known that so-called multi-junction solar cells gain from the fact that the number of subcells can be increased. However, in addition to the number of subcells, the so-called band gap energies of the materials are thereby important. These must be adapted optimally to the solar spectrum. The currently most widespread III-V solar cells consist of three p-n junctions in the materials GaInP (1.9 eV), GaInAs (1.4 eV) and germanium (0.7 eV).

The next generation of multi-junction solar cells are intended to comprise three, four or more p-n junctions with a band gap combination which is as optimal as possible in order to increase the efficiency further. The optimum band gap energies for terrestrial application in the case of a quadruple junction solar cell are hereby at 1.9, 1.4, 1.0 and 0.5 eV. It is known that this combination is difficult to achieve on germanium. An alternative combination of 1.9, 1.4, 1.1 and 0.7 eV is however only 3.5% therebelow relatively in the average power and can be produced with various material combinations.

Most current concepts are based on a lowermost subcell having a band gap energy in the region of 0.7 eV. The most important representatives are intended to be explained briefly subsequently:
GaInP/GaInAs/GaInNAs/Ge solar cell: this type of quadruple-junction solar cell is based on conventional epitaxy of III-V multi-junction solar cells on a germanium substrate. The only change from the current state of the art is the integration of an additional subcell made of the reduced nitrogen-containing material GaInNAs. As an alternative to GaInNAs, also semiconductors such as GaNAsSb or BGaInAs can be used. The concentration of N or B is in the range of 2-4%. Thus, III-V compounds can be produced, which have a band gap energy of 1.0 eV and can be grown lattice-adapted to germanium. The great problem in this approach is the material quality of the reduced N (or B)-containing materials. To date, it has not been possible to produce solar cells with high efficiency and, at the same time, with the currently widespread method of metal-organic vapour phase epitaxy. Good results have been achieved however in growth by means of molecular beam epitaxy. This method is distinguished however by significantly higher production costs for the solar cells and is therefore not used currently in industrial production. Growth of the GaInP/GaInAs/GaInNAs/Ge solar cells by means of metal-organic vapour phase epitaxy is at present not in prospect (see Volz, K. et al. (2008), Journal of Crystal Growth, vol. 310, p. 222-2228; Volz, K. et al. (2009), Proceedings of the 34^{th} IEEE Photovoltaic Solar Energy Conference, Philadelphia, USA; Essig, S. et al. (2011), Proceedings of the 9^{th} European Space Power Conference, Saint-Raphael, France). Furthermore, germanium solar cells have a relatively low open-circuit voltage which is typically in the case of the sun in the range of 260 mV.
GaInP/GaAs/GaInAsP/GaInAs solar cell: with this type of quadruple-junction solar cell, the one half of the structure is grown on a gallium arsenide substrate and the other half on an indium phosphide substrate. The desired band gaps of the materials can be achieved in principle. With this concept, the upper and lower part of the structure is connected via a wafer-bond or via mechanical stacking (see Bhusari, D. et al. (2011), Proceedings of the 37^{th} IEEE Photovoltaic Specialists Conference, Seattle, Wash., USA). The disadvantage of this structure resides in the fact that the lower subcell must be grown on an indium phosphide substrate. This substrate is extremely expensive (the costs are approx. 8-10 times higher compared with germanium and gallium arsenide.
Inverted-grown GaInP/GaAs/GaInAs/GaInAs solar cell: in this concept, all of the subcells are grown in an inverted manner on a gallium arsenide or germanium substrate. Thereafter, the structure is transferred to a substrate for stabilisation, the gallium arsenide or germanium substrate is removed and the solar cell is processed (see Friedmann, D. J. et al. (2006), Proceedings of the 4^{th} World Conference on Photovoltaic Energy Conversion, Waikoloa, Hi., USA; Stan, M. et al. (2010), Journal of Crystal Growth, vol. 312, p. 1370-1374). The low band gap energies of GaInAs in the range of 1 eV and 0.7 eV require the growth of metamorphic buffer layers having a very high strain. As a result, numerous dislocations arise which have a negative influence on the efficiency of the solar cell. Furthermore, it has emerged that the GaInAs material is less suitable for application in space since the solar cells degrade more rapidly when irradiated with high-energy electrons and protons.
GaInP/GaAs/GaInAs/Ge solar cell: here a GaInP/GaAs tandem cell is grown on gallium arsenide, then a GaInAs subcell and a metamorphic buffer structure are grown on a germanium subcell, then both parts are connected to each other in a wafer-bonding process and the gallium arsenide substrate is removed. Thus a quadruple junction solar cell structure is produced by the combination of growth on two substrates and wafer-bonding. The disadvantage of this structure resides in the fact that the lowermost subcell consists of germanium made of an indirect semiconductor and hence the absorption for wavelengths greater than 1,600 nm decreases sharply. Furthermore, germanium solar cells have a comparatively low open-circuit voltage which is typically with the sun in the region of 260 mV (see DE 2012 004 734).

It was hence the object of the present invention to provide a multi-junction solar cell which approaches as far as possible the theoretically optimum band gap combination and, at the same time, provides high quality of the subcells—in particular high absorption up to the band gap energy and a high photoelectric voltage.

The object is achieved by the multi-junction solar cell according to claim 1, the methods for the production of a multi-junction solar cell according to one of the claim 15 or 16 and the use of the multi-junction solar cell according to claim 18.

According to the invention, a multi-junction solar cell having at least three p-n junctions is provided, comprising a rear-side subcell, which has at least one p-n junction, comprising or consisting of GaSb, and a front-side subcell which has at least two p-n junctions, characterised in that the rear-side subcell has a ≧2%, in particular >4%, larger lattice constant than the front-side subcell and the two subcells are connected to each other via an optically transparent and electrically conductive wafer-bond connection.

Advantages of the multi-junction solar cell according to the invention are that it has a high absorption up to the band gap energy and a high photoelectric voltage is achieved.

The multi-junction solar cell is preferably free of Ge, SiGe and Si.

The use of gallium antimonide as component of a subcell has the advantage that it consists of elements which are widely distributed on earth, as a result of which the production can be implemented economically. It is likewise known that gallium antimonide solar cells achieve a substantially higher photoelectric voltage compared with germanium solar cells with similar band gap energy. Thus, for gallium antimonide, 349 mV was measured with the sun, compared with 264 mV for germanium. Gallium antimonide offers the advantage in addition that it concerns a direct semiconductor and hence high absorption up to the band gap energy is ensured. Furthermore, layers made of GaInAsSb can be produced lattice-adapted to the gallium antimonide substrate, which layers are even closer to the theoretically optimum band gap of 0.5 eV for the lowermost subcell of a quadruple-junction solar cell.

In an advantageous embodiment, the front-side subcell has at least two p-n junctions which comprise AlGaAs and/or GaAs and/or AlGaInP and/or GaInP or consist thereof.

The front-side subcell can have a metamorphic buffer layer for changing the lattice constant and at least one p-n junction which comprises GaInAs.

The metamorphic buffer layer changes the lattice constant, preferably by 1.5% to 3%, in particular by 2% to 2.5%.

The metamorphic buffer layer can consist of AlGaInAs or GaInAs or GaInP or AlGaInP or GaPSb.

In a preferred embodiment, the front-side subcell is grown epitaxially on a GaAs or Ge wafer.

The front-side subcell can have at least three p-n junctions, at least two p-n junctions comprising AlGaAs and/or GaAs and/or AlGaInP and/or GaInP or consisting thereof and the at least one further p-n junction comprising GaInAs or consisting thereof, the two first and the further p-n junction being connected via a metamorphic buffer which bridges a lattice constant difference between 1-5%, preferably between 2-4%.

In a preferred embodiment, the front-side subcell has three p-n junctions with a band gap in the ranges of 1.80-1.95 eV, 1.40-1.55 eV and 1.00-1.15 eV.

The rear-side subcell can have one or more p-n junctions which respectively have a band gap energy between 0.50-1.00 eV and which respectively comprise GaSb or AlGaAsSb or GaInAsSb or GaPSb or consist thereof.

It is preferred that the rear-side subcell has two p-n junctions, one p-n junction comprising GaInAsSb with a band gap energy between 0.50-0.72 eV or consisting thereof.

Furthermore, the rear-side subcell can comprise a metamorphic buffer layer for adaptation of the lattice constant, the metamorphic buffer layer consisting in particular of GaInAsSb, GaInAs, AlGaInAs, GaAsSb, AlAsSb, GaPSb and/or AlPSb.

In a preferred embodiment, the rear-side subcell is grown epitaxially on a GaSb wafer.

The individual subcells can have further functional layers, in particular tunnel diodes for electrical connection of the individual subcells, barrier layers on the front- and rear-side of the subcells, highly doped contact layers, internal reflection layers and/or antireflection layers on the front-side of the cell.

A tunnel diode for electrical series connection can be contained respectively between two subcells.

Furthermore, a method for the production of a multi-junction solar cell is provided, in which
a) a rear-side subcell comprising GaSb is grown on a substrate;
b) a front-side subcell having at least two p-n junctions made of III-V compound semiconductors is grown on a substrate made of GaAs or Ge, p-n junctions with increasing band gap energy following one after the other;
c) the front-side subcell is stabilised on the front-side by a carrier by means of a removeable adhesive and the substrate made of GaAs or Ge is removed;
d) the subcell structures from a) and c) are connected by means of wafer-bonding;
e) the carrier and the adhesive from step c) are removed;
f) the solar cell is provided with contacts and an antireflection layer.

If required, the surface of the rear-side and that of the front-side subcell can be polished and/or cleaned in the above process, after step c).

Furthermore, a method for the production of a multi-junction solar cell is provided, in which
a) a rear-side subcell comprising GaSb is grown on a substrate;
b) a front-side subcell having at least two p-n junctions made of III-V compound semiconductors is grown on a substrate made of GaAs or Ge, p-n junctions with decreasing band gap energy following one after the other;
c) the subcell structures from a) and b) are connected by means of wafer-bonding;
d) after the wafer-bonding, the substrate made of GaAs or Ge is removed;
e) the solar cell is provided with contacts and an antireflection layer.

If required, the surface of the rear-side and that of the front-side subcell can be polished and/or cleaned in the above process, after step b).

The methods according to the invention for the production of a multi-junction solar cell can be characterised in that the GaSb substrate of the rear-side subcell is removed at least partially during processing and the structure is transferred onto a carrier, preferably a carrier made of silicon, AlSi, carbon, Mo or other composites.

The multi-junction solar cell according to the invention can be used in space or in terrestrial concentrator systems.

The subject according to the invention is intended to be explained in more detail with reference to the subsequent Figures and examples without wishing to restrict said subject to the specific embodiments illustrated here.

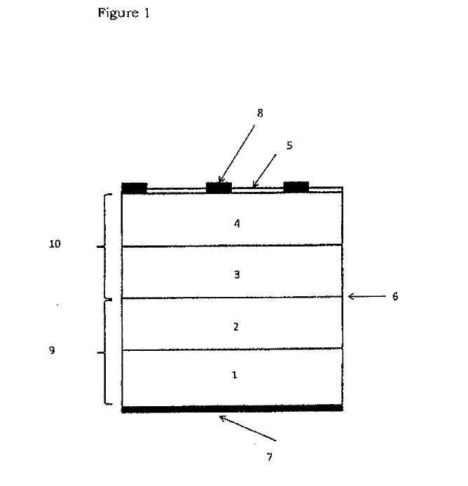

FIG. 1 shows a variant of a triple solar cell according to the invention. A first, GaSb-comprising subcell 2 having a first p-n junction is connected epitaxially to a rear-side substrate 1 which comprises GaSb or consists thereof. This can hereby concern a GaSb wafer or a thin GaSb layer which is applied on a conductive carrier (for example a GaSb layer on carrier material made of Si, AlSi, carbon, Mo or other composites). In addition, the substrate 1 has a rear-side contact 7. In the direction of the front-side, the first subcell 2 is connected to two further subcells 3 and 4 via a wafer-bond connection 6. The wafer-bond connection can be effected by direct semiconductor bonding, by bonding of amorphous semiconductor layers or by bonding of transparent conductive intermediate layers, such as indium-tin oxide. It is hereby crucial that the connection is electrically conductive and also optically transparent for the light which is absorbed in the lowermost GaSb-comprising subcell 2. In order to increase the strength, the bond connection can be heated thermally. Furthermore, the surfaces of the subcells can have been polished and/or cleaned before the bonding in order to ensure low surface roughness and also a low concentration of impurities and oxides.

On the front-side, the subcell 4 has an antirefiection layer 5 and a plurality of front-side contacts 8. The front-side contact is typically configured as a contact finger structure which is designed such that the light reflection on the metal fingers balances out resistance losses due to limited conductivity.

The subcells 2, 3 and 4 respectively have a p-n or n-p junction. The band gap energy of the semiconductors of the subcells thereby increases from 2 to 3 and from 3 to 4. The subcells can have further functional layers, such as barrier layers or tunnel diodes, for series connection. The substrate 1 and the first subcell 2 together form the rear-side subcell 9, whilst the second subcell 3 and the third subcell 4 together form the front-side subcell 10. The rear-side and front-side subcell differ in their lattice constant and are connected to each other optically and electrically via the bond connection 6.

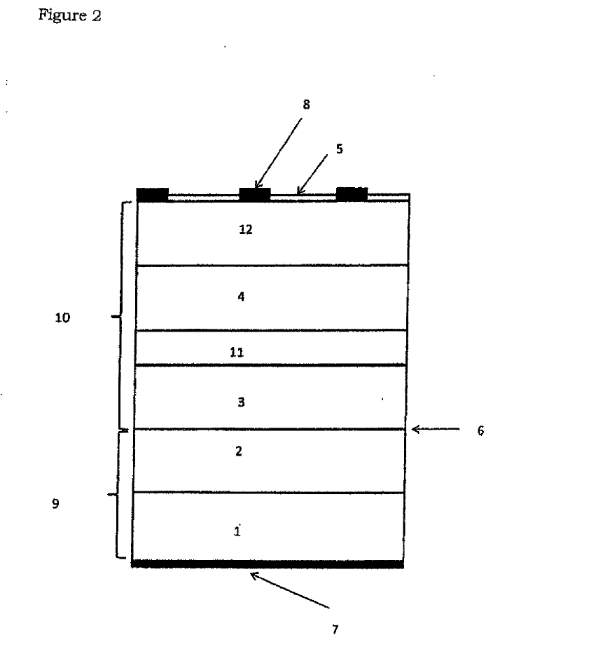

FIG. 2 shows a variant of a quadruple-junction solar cell according to the invention. The GaSb-comprising subcell 2 has a rear-side contact 7 and a substrate 1 which comprises GaSb or consists thereof. This can hereby concern a GaSb wafer or a thin GaSb layer which is applied on a conductive carrier (for example a GaSb layer on carrier material made of Si, AlSi, carbon, Mo or other composites). The first p-n junction 2 consists for example of GaSb having a band gap energy of 0.7 eV. Alternatively, also GaInAsSb having a band gap energy between 0.5-0.7 eV can be chosen, the band gap, with a constant lattice constant of GaSb, being able to be decreased by the addition of indium and arsenic in GaInAsSb. The first subcell 2 is connected to the second subcell 3 made of GaInAs via a wafer-bond connection 6. The wafer-bond connection can be effected by direct semiconductor bonding, by bonding of amorphous semiconductor layers or by bonding of transparent conductive intermediate layers, such as indium-tin oxide. It is hereby crucial that the connection is electrically conductive and also optically transparent for the light which is absorbed in the lowermost GaSb-comprising subcell. In order to increase the strength, the bond connection can be heated thermally.

The band gap of the second GaInAs subcell 3 can be adjusted via the indium content in the crystal within a wide range. In particular band gaps between 0.9 and 1.2 eV, particularly between 1.0-1.1 eV, are hereby advantageous. Between the second subcell 3 and a further third subcell 4, a metamorphic buffer layer 11 is situated, in which the lattice constant of the crystal is changed. The lattice constant of the crystal lattice can thereby be varied incrementally or linearly. The buffer layer comprises mismatch dislocations which relax the lattice. The buffer layer can furthermore comprise an excess layer for complete relaxation of the crystal lattice or blocker layers made of reduced N-containing materials. Typical materials for buffer layers are GaInAs, GaInP, AlGaInP, AlGaInAs, GaPSb and also combinations thereof.

The third subcell 4 has a band gap energy of 1.4-1.5 eV and advantageously consists of GaAs, AlGaAs or GaInAsP. Following the third subcell 4 there is a further fourth subcell 12 which has a band gap in the range of 1.8 eV-1.9 eV and advantageously consists of GaInP or AlGaInP. On the front-side, the quadruple junction solar cell has an antireflection layer 5 and a plurality of front-side contacts 8. The front-side contact is formed typically as a contact finger structure which is designed such that the light reflection on the metal fingers balances out resistance losses due to limited conductivity.

The subcells 2, 3, 4 and 12 have respectively a p-n or n-p junction. The band gap energy of the semiconductors of the subcells thereby increases from 2 to 3 to 4 to 12.

The substrate 1 and the subcell 2 together form the rear-side subcell 9 whilst the second subcell 3, the metamorphic buffer layer 11 and the third and fourth subcell 4 and 12 together form the front-side subcell 10. The rear-side and front-side subcell differ in their lattice constant and are connected to each other optically and electrically via the bond connection 6.

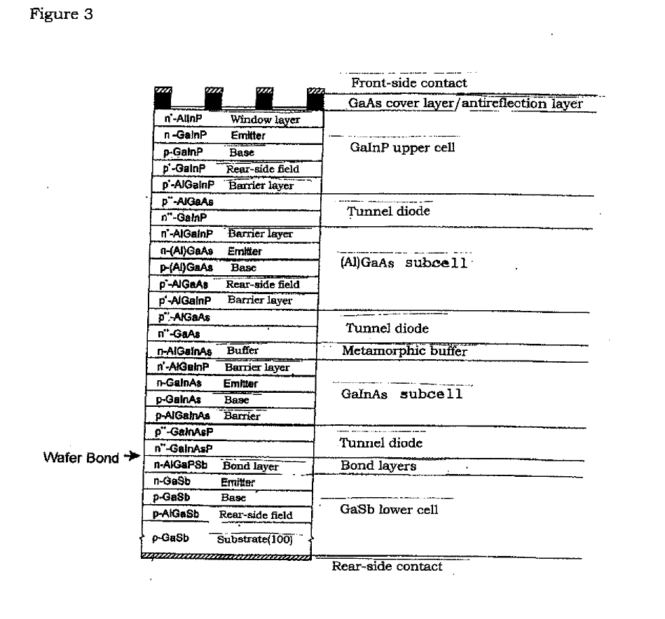

The subcells can have further functional layers, such as barrier layers or tunnel diodes, for series connection. A detailed example of an advantageous layer structure of a quadruple junction solar cell according to the invention having barrier layers and tunnel diodes is illustrated in FIG. 3. The substrate 1 consists in this case of p-GaSb. The subcell 2 comprises a p-n junction made of GaSb and also barrier layers made of n-AlGaPSb and p-AlGaSb. The subcell 3 has a p-n junction in GaInAs and barrier layers made of n-AlGaInP and p-AlGaInAs. The subcell 4 has a p-n junction in (Al)GaAs and barrier layers made of n-AlGaInP, p-AlGaAs and p-AlGaInP. The subcell 12 has a p-n junction in GaInP and barrier layers made of n-AlInP, p-GaInP and p-AlGaInP. The structure has in addition a metamorphic buffer layer 11 made of AlGaInAs. The wafer-bond connection 6 is situated between the rear-side subcell which ends with an n-AlGaPSb bond layer and the front-side subcell which ends with an n⁺⁺-GaInAsP layer of the tunnel diode. The subcells are connected respectively via tunnel diodes. The tunnel diode between subcell 2 and 3 thereby consists of p-GaInAsP and n-GaInAsP, the tunnel diode between subcell 3 and 4 consists of p-AlGaAs and n-GaAs and the tunnel diode between subcell 4 and 12 consists of p-AlGaAs and n-GaInP. The tunnel diode layers are respectively highly doped in order to ensure high tunnel current densities. The solar cell in FIG. 3 has, on the front-side of the subcell 12, a GaAs cover layer which remains only below the contacts in order to ensure a low contact resistance. Furthermore, a front-side contact is for example made of Ni/AuGe or Pd/Ge/Au. The reflection on the front-side of the solar cell is reduced by an antireflection layer which consists of dielectric layers, such as TaOx, TiOx, SiN, SiOx, SiC, MgF2, AlOx. On the rear-side of the solar cell, a planar contact having a low ohmic resistance is applied, for example made of Au/Zn/Au, Pd/In, Ti/Pd/Ag/Au, Ti/Ni/Au.

### EXAMPLE 1

### Production of Quadruple Junction Solar Cells

For example one of the following quadruple-junction solar cells can be produced:
GaInP (1.9 eV)/GaAs (1.4 eV)/GaInAs (1.1 eV)/GaSb (0.7 eV);
GaInP (1.9 eV)/GaAs (1.4 eV)/GaInAs (1.0 eV/GaInAsSb (0.5 eV);
GaInP (1.9 eV) as subcell 12, GaAs (1.4 eV) as subcell 4, GaInAs (1.1 eV) as subcell 3 and GaSb (0.7 eV) as subcell 2;
GaInP (1.9 eV) as subcell 12, GaAs (1.4 eV) as subcell 4, GaInAs (1.0 eV) as subcell 3 and GaInAsSb (0.5 eV) as subcell 2;
AlGaIInP (2.0 eV) as subcell 12, AlGaAs (1.5 eV) as subcell 4, GaInAs (1.1 eV) as subcell 3 and GaSb (0.7 eV) as subcell 2; and/or
AlGaInP (2.0 eV) as subcell 12, GaInAsP (1.5 eV) as subcell 4, GaInAs (1.1 eV) as subcell 3 and GaSb (0.7 eV) as subcell 2.

The solar cell structure can be produced for example via the following steps:
1.) On the one side, a GaInP, GaAs and GaInAs subcell is grown epitaxially on a GaAs or germanium substrate (e.g. by means of metal-organic vapour phase epitaxy);
2.) On the other side, a GaSb or GaInAsSb lower cell is grown on a gallium antimonide substrate (e.g. by means of metal-organic vapour phase epitaxy);
3.) Polishing and/or cleaning of the surfaces of the rear-side and of the front-side subcell;
4.) Connection of the two structures from 1.) and 2.) via wafer-bonding, as a result of which a quadruple-junction solar cell with optimal properties is produced (see FIG. 1);
5.) Removal of the GaAs or Ge substrate, for growth of the front-side subcell, via a removal process and possibly recycling of the substrate for further growth.

### EXAMPLE 2

### Production of a Quintuple Solar Cell

Quintuple solar cells according to the present invention can consist of a front-side subcell with p-n junctions in AlGaInP (2.0 eV), GaInAsP (1.6 eV) and GaInAs (1.2 eV), a metamorphic buffer for bridging the lattice constant difference being inserted between the GaInAsP and GaInAs subcell. The front-side subcell is grown epitaxially for example on a gallium arsenide substrate. The rear-side subcell is grown on gallium antimonide and comprises for example subcells with p-n junctions in GaPSb (0.9 eV) and GaInAsSb (0.5 eV). Between the GaPSb and GaInAsSb subcell, a metamorphic buffer layer for bridging different lattice constants can be inserted. The rear-side and the front-side subcell are subsequently bonded to each other after the epitaxy and possibly necessary polishing and cleaning steps, and the GaAs substrate of the front-side subcell is removed.

1. Multi-junction solar cell having at least three p-n junctions, comprising a rear-side subcell comprising GaSb, which has at least one p-n junction, and a front-side subcell which has at least two p-n junctions, characterised in that the rear-side subcell has a ≧2%, in particular >4%, larger lattice constant than the front-side subcell and the two subcells are connected to each other via an optically transparent and electrically conductive wafer-bond connection.

2. Multi-junction solar cell according to claim 1, characterised in that the multi-junction solar cell is free of subcells made of Si, SiGe and/or Ge.

3. Multi-junction solar cell according to one of the preceding claims, characterised in that the front-side subcell has at least two p-n junctions which comprise AlGaAs and/or GaAs and/or AlGaInP and/or GaInP or consist thereof.

4. Multi-junction solar cell according to one of the preceding claims, characterised in that the front-side subcell has a metamorphic buffer layer for changing the lattice constant and at least one p-n junction which comprises GaInAs.

5. Multi-junction solar cell according to claim 3, characterised in that the metamorphic buffer layer changes the lattice constant by 1.5% to 3%, in particular by 2% to 2.5%.

6. Multi-junction solar cell according to claim 3, characterised in that the metamorphic buffer layer consists of AlGaInAs or GaInAs or GaInP or AlGaInP or GaPSb.

7. Multi-junction solar cell according to one of the preceding claims, characterised in that the front-side subcell is grown epitaxially on a GaAs or Ge wafer.

8. Multi-junction solar cell according to one of the preceding claims, characterised in that the front-side subcell has at least three p-n junctions, at least two p-n junctions comprising AlGaAs and/or GaAs and/or AlGaInP and/or GaInP or consisting thereof and the at least one further p-n junction comprising GaInAs or consisting thereof, the two first and the further p-n junction being connected via a metamorphic buffer which bridges a lattice constant difference between 1-5%, preferably between 2-4%.

9. Multi-junction solar cell according to one of the preceding claims, characterised in that the front-side subcell has three p-n junctions with a band gap in the ranges of 1.80-1.95 eV, 1.40-1.55 eV and 1.00-1.15 eV.

10. Multi-junction solar cell according to one of the preceding claims, characterised in that the rear-side subcell has one or more p-n junctions which respectively have a band gap energy between 0.50-1.00 eV and which respectively comprise GaSb or AlGaAsSb or GaInAsSb or GaPSb or consist thereof.

11. Multi-junction solar cell according to one of the preceding claims, characterised in that the rear-side subcell has two p-n junctions, one p-n junction comprising GaInAsSb with a band gap energy between 0.50-0.72 eV or consisting thereof.

12. Multi-junction solar cell according to one of the preceding claims, characterised in that the rear-side subcell comprises a metamorphic buffer layer for adaptation of the lattice constant, the metamorphic buffer layer consisting in particular of GaInAsSb, GaInAs, AlGaInAs, GaAsSb, AlAsSb, GaPSb and/or AlPSb.

13. Multi-junction solar cell according to one of the preceding claims, characterised in that the rear-side subcell is grown epitaxially on a GaSb wafer.

14. Multi-junction solar cell according to one of the preceding claims, characterised in that the individual subcells have further functional protective layers, in particular tunnel diodes, for electrical connection of the individual subcells, barrier layers on the front- and rear-side of the subcells, highly doped contact layers, internal reflection layers and/or antireflection layers on the front-side of the cell.

15. Multi-junction solar cell according to one of the preceding claims, characterised in that a tunnel diode for electrical series connection is contained respectively between two subcells.

16. Method for the production of a multi-junction solar cell according to one of the claims 1 to 15, in which
a) a rear-side subcell comprising GaSb is grown on a substrate;
b) a front-side subcell having at least two p-n junctions made of III-V compound semiconductors is grown on a substrate made of GaAs or Ge, p-n junctions with increasing band gap energy following one after the other;
c) the front-side subcell is stabilised on the front-side by a carrier by means of a removeable adhesive and the substrate made of GaAs or Ge is removed;
d) the subcell structures from a) and c) are connected by means of wafer-bonding;
e) the carrier and the adhesive from step c) are removed;
f) the solar cell is provided with contacts and an antireflection layer.

17. Method for the production of a multi-junction solar cell according to one of the claims 1 to 15, in which
a) a rear-side subcell comprising GaSb is grown on a substrate;
b) a front-side subcell having at least two p-n junctions made of III-V compound semiconductors is grown on a substrate made of GaAs or Ge, p-n junctions with decreasing band gap energy following one after the other;
c) the subcell structures from a) and b) are connected by means of wafer-bonding;
d) after the wafer-bonding, the substrate made of GaAs or Ge is removed;
e) the solar cell is provided with contacts and an antireflection layer.

18. Method for the production of a multi-junction solar cell according to one of the claim 16 or 17, characterised in that the GaSb substrate of the rear-side subcell is removed at least partially during processing and the structure is transferred onto a carrier, preferably a carrier made of silicon.

19. Use of the multi-junction solar cell according to one of the claims 1 to 15, in space or in terrestrial concentrator systems.
